(19) United States
(12) Patent Application Publication
(10) Pub. No.: US 2002/0012373 A1
(43) Pub. Date: Jan. 31, 2002

(54) Semiconductor laser device and method of fabricating same

(75) Inventors: Mikihiro Yokozeki, Tokyo (JP); Norihiro Iwai, Tokyo (JP); Akihiko Kasukawa, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: The Furukawa Electric Co., Ltd., Chiyoda-ku (JP)

(21) Appl. No.: 09/915,385

(22) Filed: Jul. 27, 2001

(30) Foreign Application Priority Data
Jul. 28, 2000 (JP) 2000-228485
Jun. 8, 2001 (JP) 2001-173898

(51) Int. Cl. H01S 5/00

(52) U.S. Cl. 372/46

(57) ABSTRACT

A method including the steps of: consecutively depositing a first etch stop layer, a first compound semiconductor and a second compound semiconductor layer overlying a semiconductor substrate, the first etch stop layer, the first and second compound semiconductor layers having different compositions from one another, etching the first and second compound semiconductor layers until the etching stops at the first etch stop layer, and forming a semiconductor laser device including the first etch stop layer and the first and second compound semiconductor layers. The existence of the first compound semiconductor layer made of a material different from those of the second compound semiconductor layer and the etch stop layer enables the etching of the second compound semiconductor layer while controlling the etching depth thereof by using the etch stop layer.

### BACKGROUND OF THE INVENTION

(a) Field of the Invention

The present invention relates to a semiconductor laser device, more in detail to the semiconductor laser device having excellent lasing characteristics and high reliability, for example, most suitable for a semiconductor laser device of a 980 nm band, and a method of fabricating the same.

(b) Description of the Related Art

A semiconductor laser device of a 980 nm band is attracting the public attention as a higher output-power semiconductor laser device used as an excitation optical source in an erbium-doped fiber amplifier (EDFA) system, and the research and development thereof are progressing.

In the step of fabricating the semiconductor laser device including the internal stripe structure, after an n-type current blocking layer is etched to a striped structure, a p-type cladding layer is formed thereon.

It is quite important in fabricating the semiconductor laser device having excellent lasing characteristics that the etching depth is strictly controlled to etch only a layer to be etched (etched layer), thereby not over-etching the layer underlying the etched layer.

Although the etching depth is ordinarily controlled by adjusting an etching rate or a length of etching time, the accurate control is difficult. Accordingly, an etch stopper is frequently formed underlying the etched layer to automatically stop the progress of the etching at the surface of the etch stopper.

The etch stopper having etching selectivity is made of a material having an etching rate with respect to an etching gas or an etchant significantly lower than that of the etched layer. The formation of the etch stopper under the etched layer automatically stops the progress of the etching because of the difference of the etching rates.

The etch stopper is indispensable in the fabrication of the semiconductor laser device requiring the strict control of the etching depth of the current blocking layer, especially of a higher output self-aligned structure (SAS) semiconductor laser device of the 980 nm band used as an excitation optical source of the EDFA system.

The 980 nm band semiconductor laser device includes an InGaAs layer as an active layer, and an AlGaAs layer as a cladding layer overlying an n-GaAs substrate.

In practice, after the n-AlGaAs cladding layer, the InGaAs active layer, a p-AlGaAs cladding layer, an n-AlGaAs current blocking layer and an n-GaAs cap layer are stacked, the n-AlGaAs current blocking layer and the n-GaAs cap layer are stacked overlying a GaAs substrate, the n-GaAs cap layer and the n-AlGaAs current blocking layer are etched to expose the p-AlGaAs cladding layer. In this process, an In_{0.49}Ga_{0.51}P layer is used as the etch stopper having the etching selectively with respect to the AlGaAs layer and being lattice-matched with the GaAs substrate.

The use of an SCH layer is proposed in which the layers made of non-doped AlGaAs is disposed between the n-AlGaAs cladding and the InGaAs active layer and between the active layer and the p-AlGaAs cladding layer depending on necessity.

A two-layered etch stopper is also proposed as an alternative.

Then, the fabrication of the 980 nm band semiconductor laser device having a two-layered etch stopper will be described.

A first n-Al_{0.3}Ga_{0.7}As cladding layer, a first Al_{0.2}Ga_{0.8}As SCH layer, a first GaAs_{0.9}P_{0.1} barrier layer, an In_{0.2}Ga_{0.8}As active layer, a second GaAs_{0.9}P_{0.1} barrier layer, and a second Al_{0.2}Ga_{0.8}As SCH layer are sequentially stacked on an n-GaAs substrate.

Further, on the second Al_{0.2}Ga_{0.8}As SCH layer are sequentially stacked a second p-Al_{0.3}Ga_{0.7}As cladding layer, a first p-GaAs etch stop layer having a thickness of 10 nm, a second n-In_{0.49}Ga_{0.51}P etch stop layer having a thickness of 10 nm, an n-Al_{0.35}Ga_{0.65}As current blocking layer having a thickness of 200 nm, and a p-GaAs cap layer.

In order to obtain the semiconductor laser device, only the n-Al_{0.35}Ga_{0.65}As current blocking layer and the p-GaAs cap layer should be etched to form a stripe. Accordingly, an etching mask is deposited for etching the two layers.

Subsequently, the p-GaAs cap layer and the n-Al_{0.35}Ga_{0.65}As current blocking layer are etched using an etching solution containing an etchant such as tartaric acid and citric acid having etching selectivity with respect to the second n-In_{0.49}Ga_{0.51}P etch stop layer. After the stop of the etching by using the second etch stop layer, the etching mask is removed.

Then, the second etch stop layer is removed by using a hydrochloric acid-based etchant (HCl: H₂PO₄=1:3) having etching selectivity with respect to the first etch stop layer. The progress of the etching is stopped at the first etch stop layer.

Thereafter, the p-Al_{0.3}Ga_{0.7}As cladding layer and the GaAs cap layer are re-grown on the p-GaAs cap layer and the first etch stop layer, thereby fabricating the 980 nm band semiconductor laser device.

However, in this conventional method, an intermediate layer is formed between the second etch stop layer and the current blocking layer. The composition of the intermediate layer different from both of the second etch stop layer and the current blocking layer reduces the durability of the second etch stop layer and exposes the n-Al_{0.3}Ga_{0.7}As cladding layer to the re-grown surface. Consequently, the operation voltage and the threshold current are significantly increased.

The lasing characteristics and the reliability are not satisfactory on the practical basis, and further improvements have been desired.

The above semiconductor laser device had a stripe width of 2.5 μm, a cavity length of 1200 μm, an anti-reflection(AR) film having a reflection rate of 5% formed on the front cleavage facet, and higher reflection (HR) films having a reflection rate of 92% formed on the front and the rear cleavage facets. When the durability of the second etch stop layer was maintained and the etching stopped at the surface of the second etch stop layer during the fabrication of the semiconductor laser device having the above configuration by etching the cap layer and the current blocking layer, the threshold current was 17 mA, and the operation voltage was 1.4 V in case of the injected current of 100 mA.

When the durability of the second etch stop layer of the same semiconductor laser device was deteriorated to expose the n-Al_{0.3}Ga_{0.7}As cladding layer to the re-grown surface, the threshold current increased to 40 to 100 mA, and the operation voltage increased to 1.7 to 2.0 V in case of the injected current of 100 mA.

The occurrence of the problem is not restricted to the two-layered etch stop layer described above and to the fabrication of the 980 nm band semiconductor laser device. The problem may arise between any etched layer and any etch stop layer.

The compound semiconductor layer of the semiconductor laser device is frequently etched to provide a desired structure. For example, the top section of the stacked structure including the compound semiconductor layer is etched for ridge formation, and a single compound semiconductor layer is etched for aperture formation. In both cases, the same problem arises when the etch stop layer is disposed under the etched layer.

### SUMMARY OF THE INVENTION

In one aspect of the present invention, a method is provided including the steps of: consecutively depositing a first etch stop layer, a first compound semiconductor and a second compound semiconductor layer overlying a semiconductor substrate, the first etch stop layer, the first and second compound semiconductor layers having different compositions from one another, etching the first and second compound semiconductor layers until the etching stops at the first etch stop layer, and forming a semiconductor laser device including the first etch stop layer and the first and second compound semiconductor layers.

In another aspect of the present invention, a semiconductor laser device is provided which is fabricated by the above method.

In accordance with these aspects of the invention, the existence of the first compound semiconductor layer made of a material different from those of the second compound semiconductor layer and the etch stop layer and disposing therebetween enables the etching of the second compound semiconductor layer while controlling the etching depth thereof by using the etch stop layer, thereby increasing the anti-etching durability of the etch stop layer and the etching accuracy to realize the semiconductor laser device having the excellent lasing characteristics and reliability.

The above and other objects, features and advantages of the present invention will be more apparent from the following description.

### BRIEF DESCRIPTION OF DRAWINGS

FIGS. 1A and 1B are schematic vertical sectional views showing a conventional method of fabricating a semiconductor laser device and a drawback in the method, respectively.

FIG. 2 is a vertical sectional view showing a semiconductor laser device in accordance with an embodiment of the present invention.

FIGS. 3A to 3C are vertical sectional views sequentially showing a method for fabricating the semiconductor laser device of FIG. 2.

### PREFERRED EMBODIMENTS OF THE INVENTION

The present inventors have investigated the reasons of the unsatisfactory lasing characteristics and reliability of the conventional 980 nm band semiconductor laser device fabricated in accordance with the conventional method, thereby discovering the following results.

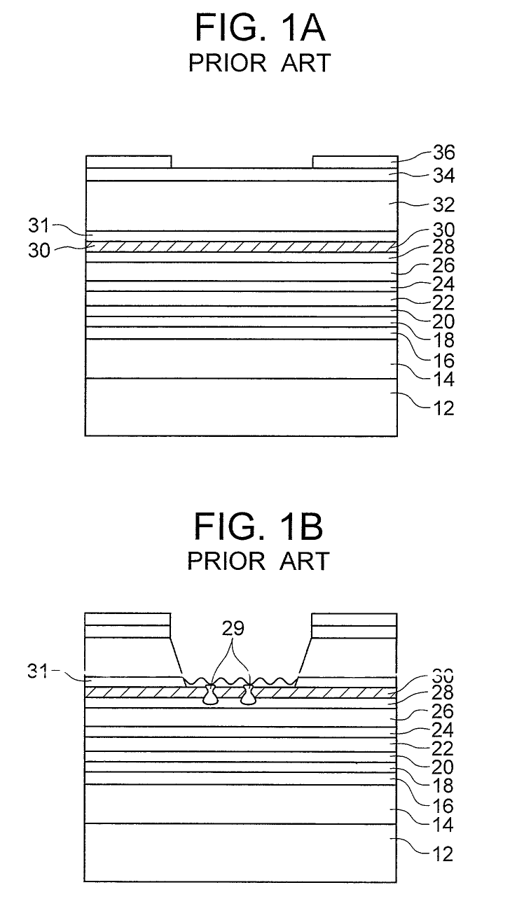

As shown in FIG. 1A showing a schematic sectional view of the conventional semiconductor laser device, when an n-Al_{0.35}Ga_{0.65}As current blocking layer 32 is grown on an In_{0.49}Ga_{0.51}P second etch stop layer 30, an intermediate layer 31 is generated at the interface thereof having a complicated and non-uniform composition containing the atoms of the second etch stop layer 30 and the current blocking layer 32.

When the current blocking layer 32 is ideally grown on the second etch stop layer 30 or, for example, the current blocking layer 32 is grown in experimentally ideal conditions, the intermediate layer 31 is not grown. However, in the actual growing step, the intermediate layer 31 is grown made of the atoms complicatedly mixed when the current blocking layer 32 is grown at a practical speed by using the MOCVD method.

Since the etching rate is also non-uniform in the intermediate layer 31, the surface of the p-In_{0.49}Ga_{0.51}P second etch stop layer 30 is non-uniformly etched to make an uneven surface when the n-Al_{0.35}Ga_{0.65}As current blocking layer 32 is etched.

Accordingly, as shown in FIG. 1B, when the second etch stop layer 30 is as thin as below 10 nm, partial apertures 29 are perforated in the second etch stop layer 30 such that the p-GaAs first etch stop layer 28 and the n-Al_{0.3}Ga_{0.7}As cladding layer 26 are also etched.

Further, when the n-Al_{0.3}Ga_{0.7}As cladding layer 26 or the Al-containing material is exposed to the re-grown surface, the crystal defects are generated due to the surface oxidation of the Al-containing material during the re-growing of a p-Al_{0.3}Ga_{0.7}As cladding layer. Accordingly, the laser characteristics and the reliability of the semiconductor laser device are lowered.

For example, after the p-Al_{0.3}Ga_{0.7}As cladding layer was re-grown on the p-Al_{0.3}Ga_{0.7}As cladding layer 26 to fabricate the semiconductor laser device, the lasing characteristics were evaluated. As a result, an operation voltage and a threshold voltage were remarkably increased.

The intermediate layer formed at the interface between the current blocking layer 32 and the second etch stop layer 30 causes a problem that the second etch stop layer 30 around the intermediate layer is difficult to be locally removed.

The repeated experiments by the inventors have reached to the present invention under the conception that a compound semiconductor layer such as a GaAs layer made of a material different from those of the current blocking layer 32 and the second etch stop layer 30 is inserted therebetween such that the current blocking layer 32 and the second etch stop layer 30 are separated from each other to prevent the formation of the intermediate layer, thereby increasing the anti-etching durability of the second etch stop layer 30.

In the present invention, the film thicknesses of the second compound semiconductor layer and the etch stop layer are not restricted, and the film thickness of the first compound semiconductor layer is preferably 0.3 nm or more. The effect of the invention cannot be satisfactorily obtained at the thickness below 0.3 nm.

The materials of the first compound semiconductor layer, the second compound semiconductor layer and the etch stop layer are different among one another, and the first compound semiconductor layer is lattice-matched with the substrate.

In a preferred embodiment of the 980 nm semiconductor laser device including the combination of the AlGaAs etched layer and the InGaP etch stop layer, the second compound semiconductor layer includes aluminum, the etch stop layer is a compound semiconductor layer including at least phosphorus, and the first compound semiconductor layer includes neither of aluminum nor phosphorus.

The present invention may be suitably applied to the semiconductor laser device in which the above intermediate layer is liable to be generated between the etched layer and the etch stop layer.

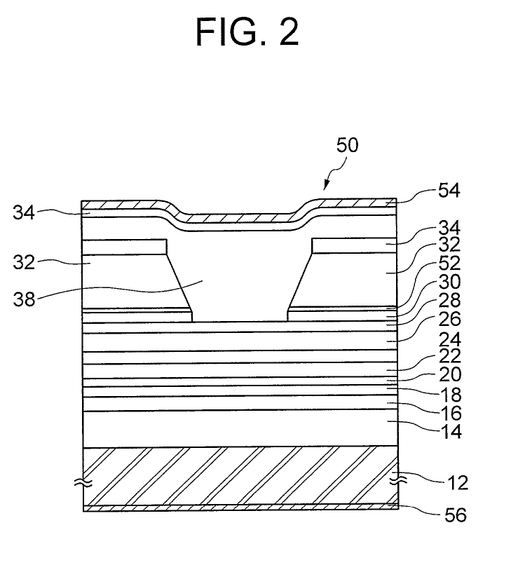

Then, the configuration of a semiconductor laser device of an embodiment in accordance with the second invention will be described referring to FIG. 2.

As shown in FIG. 2, a semiconductor laser device 50 of the present embodiment has a stacked layer including a first n-Al_{0.3}Ga_{0.7}As cladding layer 14, a first Al_{0.2}Ga_{0.8}As SCH layer 16, a first GaAs_{0.9}P_{0.1} barrier layer 18, an In_{0.2}Ga_{0.8}As active layer 20, a second GaAs_{0.9}P_{0.1} barrier layer 22, and a second Al_{0.2}Ga_{0.8}As SCH layer 24 sequentially stacked on an n-GaAs substrate 12, similarly to the conventional semiconductor laser device.

Further, on the second Al_{0.2}Ga_{0.8}As SCH layer 24 are sequentially stacked a second p-Al_{0.3}Ga_{0.7}As cladding layer 26, a first p-GaAs etch stop layer 28 having a thickness of 10 nm, a second n-In_{0.49}Ga_{0.51}P etch stop layer 30 having a thickness of 10 nm, an n-Al_{0.35}Ga_{0.65}As current blocking layer 32 having a thickness of 200 nm, and a p-GaAs cap layer 34, and different from the conventional semiconductor laser device, an n-GaAs layer 52 having a thickness of 5 nm is disposed between the second etch stop layer 30 and the current blocking layer 32.

A p-type electrode 54 is formed on the p-GaAs cap layer 34, and an n-type electrode 56 is formed on the bottom surface of the n-GaAs substrate 12.

Since the existence of the n-GaAs layer 52 separates the n-Al_{0.35}Ga_{0.65}As current blocking layer 32 and the second n-In_{0.49}Ga_{0.51}P etch stop layer 30 from each other, the interface heretofore formed is not substantially formed between the current blocking layer 32 and the second etch stop layer 30. Accordingly, the intermediate layer made of the variety of atoms non-uniformly mixed is not formed.

The absence of the intermediate layer could be confirmed by using a transmission electron microscope, and the operation voltage and the threshold voltage of the semiconductor laser device 50 of the embodiment were significantly decreased in comparison with those of the conventional semiconductor laser device including no n-GaAs layer.

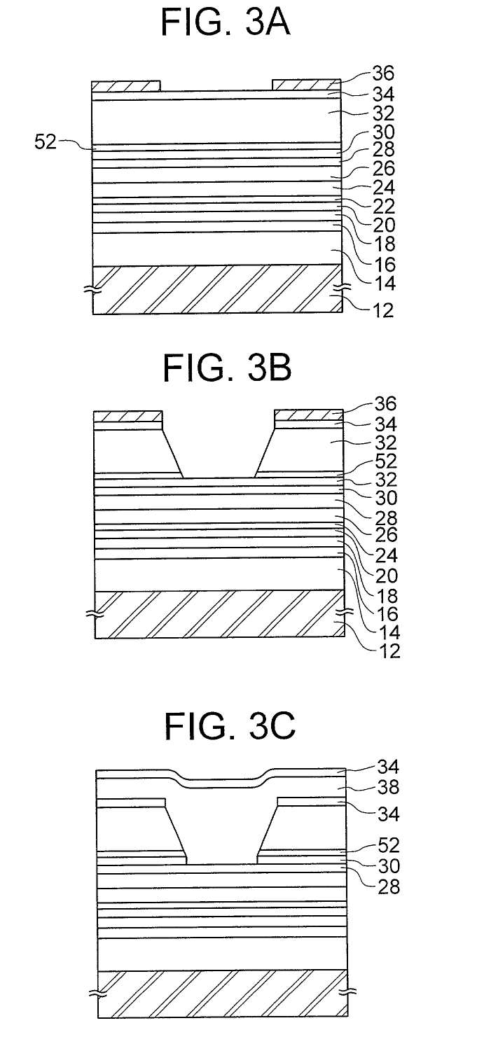

Then, a method for fabricating the semiconductor laser device of the embodiment will be described referring to FIGS. 3A to 3C.

As shown in FIG. 3A, the first n-Al_{0.3}Ga_{0.7}As cladding layer 14, the first Al_{0.2}Ga_{0.8}As SCH layer 16, the first GaAs_{0.9}P_{0.1} barrier layer 18, the In_{0.2}Ga_{0.8}As active layer 20, the second GaAs_{0.9}P_{0.1} barrier layer 22, and the second Al_{0.2}Ga_{0.8}As SCH layer 24 are sequentially stacked on the n-GaAs substrate 12, similarly to the conventional semiconductor laser device.

Further, on the second Al_{0.2}Ga_{0.8}As SCH layer 24 are sequentially stacked the second p-Al_{0.3}Ga_{0.7}As cladding layer 26, the first p-GaAs etch stop layer 28 having the thickness of 10 nm, the second n-In_{0.49}Ga_{0.51}P etch stop layer 30 having the thickness of 10 nm, the GaAs layer 52 having a thickness of 5 nm, the n-Al_{0.35}Ga_{0.65}As current blocking layer 32 having the thickness of 200 nm, and the p-GaAs cap layer 34.

Then, as shown in FIG. 3A, an etching mask 36 is deposited for etching the p-GaAs cap layer 34 and the n-Al_{0.35}Ga_{0.65}As current blocking layer 32.

Subsequently, as shown in FIG. 3B, the p-GaAs cap layer 34, the n-Al_{0.35}Ga_{0.65}As current blocking layer 32 and the n-GaAs layer 52 are etched using an etching solution containing an etchant such as tartaric acid and citric acid having etching selectivity with respect to the second n-In_{0.49}Ga_{0.51}P etch stop layer 30. After the stop of the etching by using the second etch stop layer 30, the etching mask is removed.

Then, as shown in FIG. 3C, the second etch stop layer 30 is removed by using a hydrochloric acid-based etchant (HCl:H₂PO₄=1:3) having etching selectivity with respect to the first etch stop layer 28.

Thereafter, the p-Al_{0.3}Ga_{0.7}As cladding layer 38 and the GaAs cap layer 34 are re-grown on the p-GaAs cap layer 34 and the exposed first etch stop layer 28. The resulting structure is referred to as the self-aligned structure (SAS).

Then, the p-type electrode 54 is formed on the p-GaAs cap layer 34, and the n-type electrode 56 is formed on the bottom surface of the n-GaAs substrate 12, thereby providing the 980 nm band semiconductor laser device structure 50.

Also in the semiconductor laser device fabricated by the above method, the interface is not formed for preventing the formation of the intermediate layer.

The second etch stop layer 30 is not hardly present having the uniform thickness on the entire layer during the etching of the current blocking layer because the formation of the intermediate layer prevents the local sway of the second etch stop layer 30. Therefore, the anti-etch stopping durability of the second etch stop layer 30 increases, and even if the thickness of the second etch stop layer 30 is 10 nm or less, the apertures are not locally perforated due to the etching.

The increase of the anti-etch stopping durability, and the formation of the re-grown surface without surface roughness could be confirmed by using a reflection electron microscope.

The prevention of the intermediate layer formation by the insertion of the n-GaAs layer 52 does not arise a conventional problem that the smooth etching of the second etch stop layer 30 is hardly conducted by the intermediate layer formation.

The lasing characteristics of the semiconductor laser device fabricated in this manner were measured. As a result, the operation voltage and the threshold voltage were remarkably decreased compared with the conventional semiconductor laser device in which the Al_{0.3}Ga_{0.7}As cladding layer is exposed due to the absence of the GaAs layer on the surface thereof.

The present embodiment could be applied to other combinations than the combination of the AlGaAs etched layer and the InGaP etch stop layer.

Since the above embodiment is described only for examples, the present invention is not limited to the above embodiment and various modifications or alterations can be easily made therefrom by those skilled in the art without departing from the scope of the present invention.

What is claimed is:

1. A method comprising the steps of: consecutively depositing a first etch stop layer, a first compound semiconductor and a second compound semiconductor layer overlying a semiconductor substrate, the first etch stop layer, the first and second compound semiconductor layers having different compositions from one another, etching the first and second compound semiconductor layers until the etching stops at the first etch stop layer, and forming a semiconductor laser device including the first etch stop layer and the first and second compound semiconductor layers.

2. The method as defined in claim 1 further comprising the steps of:
depositing a second etch stop layer having etching selectivity with respect to the first etch stop layer overlying the semiconductor substrate before the first etch stop layer depositing step; and
etching the first etch stop layer using the second etch stop layer.

3. A semiconductor laser device fabricated by the method as defined in claim 1.

4. The semiconductor laser device as defined in claim 3, wherein the first compound semiconductor layer contains at least aluminum, the second compound semiconductor layer contains neither of aluminum nor phosphorus, and the first etch stop layer contains at least phosphorus.

5. The semiconductor laser device as defined in claim 1, wherein the first compound semiconductor layer, the second compound semiconductor layer and the first etch stop layer are an AlGaAs layer, a GaAs layer and an InGaP layer, respectively.
